(19) United States
(12) Patent Application Publication
(10) Pub. No.: US 2015/0144595 A1
(43) Pub. Date: May 28, 2015

(54) GAS CLUSTER IRRADIATION MECHANISM, SUBSTRATE PROCESSING APPARATUS USING SAME, AND GAS CLUSTER IRRADIATION METHOD

(71) Applicant: Tokyo Electron Limited, Tokyo (JP)

(72) Inventors: Kensuke Inai, Yamanashi (JP); Kazuya Dobashi, Yamanashi (JP)

(73) Assignee: Tokyo Electron Limited, Tokyo (JP)

(21) Appl. No.: 14/412,661

(22) PCT Filed: May 22, 2013
(86) PCT No.: PCT/JP2013/064248

§ 371 Date: Jan. 2, 2015

(30) Foreign Application Priority Data
Jul. 4, 2012 (JP) 2012-150695

(51) Int. Cl. H01J 37/32; B08B 7/00

(52) U.S. Cl. CPC H01J 37/3244; B08B 7/005; H01J 37/32743
USPC 216/63; 134/1.3; 156/345.33; 156/345.31

(57) ABSTRACT

A gas cluster irradiation mechanism includes at least one nozzle unit having a plurality of gas injection nozzles, and a gas supply unit for supplying the gas to the nozzle unit. The plurality of the gas injection nozzles is set such that when the gas is supplied from the gas injection nozzles at a preset flow rate a pressure in the processing chamber remains below a limit at which the gas cluster begins to be destroyed. Further, the gas injection nozzles are arranged with a preset interval between neighboring gas injection nozzle such that respective areas in which residual gas from the neighboring gas injection nozzles spreads do not overlap with each other, the residual gas being part of the gas injected from the gas injection nozzles and not contributing to generation of the gas cluster.

### CROSSREFERENCE

This application is a national stage application of PCT application No. PCT/JP2013/064248 filed on May 22, 2013, which claims priority and benefit to Japanese Patent Application No. 2012-150695 filed on Jul. 4, 2012. The contents of the foregoing applications are herein incorporated by reference.

### FIELD OF THE INVENTION

The present invention relates to a gas cluster irradiation mechanism, a substrate processing apparatus using the same, and a gas cluster irradiation method.

### BACKGROUND OF THE INVENTION

Recently, a gas cluster technique for processing or cleaning a sample surface by irradiating a gas cluster onto the sample surface attracts attention as a technique capable of performing processing or cleaning with high selectivity.

As for a method for irradiating the gas cluster onto the sample surface, there is known, e.g., a method using a gas cluster ion beam, in which a gas cluster ionized and accelerated by an electric field or a magnetic field is made to collide with the sample surface (see, e.g., Patent Document 1: Japanese Application Publication No. H8-319105).

In the method using the gas cluster ion beam, the cluster is ionized and, thus, the substrate may be electrically damaged. To that end, the cluster ion is electrically neutralized by a neutralizer or the like and then is made to collide with the sample. However, the above method cannot completely neutralize the cluster.

As for a gas cluster irradiation technique that does not cause electrical damage, there is suggested a technique for irradiating a neutral gas cluster by using adiabatic expansion of a gas (Patent Document 2: PCT Patent Publication No. WO2010/021265).

In Patent Document 2, a reactive cluster is generated by adiabatic expansion, by injecting from a gas injection unit a gaseous mixture of ClF₃ gas as a reactive gas and Ar gas as a gas having a boiling point lower than that of the reactive gas into a vacuum processing chamber at a pressure in a range in which the mixed gas is not liquefied and, then, the reactive cluster is injected to a sample surface in the vacuum processing chamber to process the sample surface.

In the technique disclosed in Patent Document 2, the cluster is generated by injecting a gas from a single injection unit (nozzle). However, the gas cluster generated from the single nozzle is irradiated onto an area of several mmφ. Therefore, a throughput becomes a problem in the case of applying such a technique to processing of a large-sized substrate such as a semiconductor wafer.

The throughput problem can be solved by providing a plurality of gas injection nozzles. However, if the plurality of gas injection nozzles is provided, a gas flow rate is increased and a vacuum degree is decreased. Accordingly, the processing performance deteriorates. In other words, the decrease in the vacuum degree leads to destruction of the gas cluster. Therefore, when the vacuum degree becomes lower than a predetermined level by the increase in the number of nozzles, the gas cluster is destroyed and the processing performance deteriorates. Further, the vacuum degree may be locally decreased even when a proper number of nozzles are provided. In that case, the processing performance deteriorates at that portion.

### SUMMARY OF THE INVENTION

In view of the above, the present invention provides a gas cluster irradiation mechanism and a gas cluster irradiation method which can perform processing using a gas cluster with high throughput without destroying the gas cluster, and a substrate processing device including the gas cluster irradiation mechanism.

In accordance with one aspect of the invention, there is provided a gas cluster irradiation mechanism for generating a gas cluster by adiabatic expansion of a gas and irradiating the gas cluster onto a substrate to be processed in the processing chamber, the gas cluster irradiation mechanism comprising: at least one nozzle unit including a number of gas injection nozzles configured to inject the gas into the processing chamber which is maintained in a vacuum state; and a gas supply unit configured to supply the gas to the nozzle unit, wherein the number of the gas injection nozzles is set such that when the gas is supplied from the gas injection nozzles at a preset flow rate a pressure in the processing chamber remains below a limit at which the gas cluster begins to be destroyed, and wherein the gas injection nozzles are arranged with a preset interval between neighboring gas injection nozzle such that respective areas in which residual gas from the neighboring gas injection nozzles spreads do not overlap with each other, the residual gas being part of the gas injected from the gas injection nozzles and not contributing to generation of the gas cluster.

In the above gas cluster irradiation mechanism, the pressure in the processing chamber is 0.3 kPa or less when a supply pressure of the gas to said at least one nozzle unit is 1 MPa or less and the pressure in the processing chamber is 3 kPa or less when the supply pressure is greater than 1 MPa and smaller than or equal to 5 MPa.

In the above gas cluster irradiation mechanism, a distance between the neighboring gas injection nozzles among the number of gas injection nozzles is 20 mm or greater and said at least one nozzle unit and the substrate to be processed are relatively movable with respect to each other. And the gas cluster is irradiated onto the entirety of one side of the substrate to be processed while relatively moving said at least one nozzle unit and the substrate to be processed.

In the above gas cluster irradiation mechanism, said at least one nozzle unit comprises a plurality of nozzle units which are configured such that the gas is injected from each of the plurality of nozzle units sequentially. In this case, positions of corresponding gas injection nozzles of adjacent nozzle units among the plurality of nozzle units are misaligned. And a misalignment distance of the corresponding gas injection nozzles of the adjacent nozzle units is smaller than or equal to an irradiation range of the gas cluster from a single gas injection nozzle, and wherein the number of the gas injection nozzles is set such that an irradiation rage of the gas cluster from the entirety of the gas injection nozzles cover the entirety of the substrate to be processed in a diametrical direction of the substrate to be processed.

In the above gas cluster irradiation mechanism, the gas cluster irradiation mechanism is configured to be provided in a vacuum transfer chamber or a load-lock chamber for transferring the substrate to be processed to the processing chamber, and the gas cluster irradiation mechanism is configured such that the gas cluster is irradiated in a state where the substrate to be processed is mounted on a transfer arm which transfers the substrate to be processed.

In accordance with another aspect of the invention, there is provided a substrate processing apparatus for performing predetermined processing on a substrate to be processed by using a gas cluster, comprising: a processing chamber maintained in a vacuum state; a substrate supporting unit configured to support the substrate to be processed in the processing chamber; and a gas cluster irradiation mechanism for generating the gas cluster by adiabatic expansion a gas into the processing chamber and irradiating the gas cluster onto the substrate to be processed, wherein the gas cluster irradiation mechanism includes: at least one nozzle unit having a number of gas injection nozzles configured to inject the gas into the processing chamber which is maintained in a vacuum state; and a gas supply unit configured to supply the gas to the nozzle unit, wherein the number of the gas injection nozzles of the nozzle unit is set such that when the gas is supplied from the gas injection nozzles at a preset flow rate a pressure in the processing chamber remains below a limit at which the gas cluster begins to be destroyed, and wherein the gas injection nozzles are arranged with a preset interval between neighboring gas injection nozzles such that respective areas in which residual gas from the neighboring gas injection nozzles spreads do not overlap with each other, the residual gas being part of the gas injected from the gas injection nozzles and not contributing to generation of the gas cluster.

In accordance with still another aspect of the invention, there is provided a gas cluster processing method, comprising: generating a gas cluster by adiabatic expansion by injecting a gas into a processing chamber maintained in a vacuum state and irradiating the gas cluster onto a substrate to be processed in the processing chamber, wherein the number of the gas injection nozzles is set such that when the gas is supplied from the gas injection nozzles at a preset flow rate a pressure in the processing chamber remains below a limit at which the gas cluster begins to be destroyed, and wherein the gas injection nozzles are arranged with a preset interval between neighboring gas injection nozzles such that respective areas in which residual gas from the neighboring gas injection nozzles spreads do not overlap with each other, the residual gas being part of the gas injected from the gas injection nozzles and not contributing to generation of the gas cluster.

In accordance with the present invention, the number of gas injection nozzles is set so that the pressure in the processing chamber does not destroy the gas cluster when the gas is supplied from the gas injection nozzles at a required flow rate. Further, neighboring gas injection nozzles are arranged so that areas in which residual gas therefrom spreads do not overlap with each other, the residual gas being part of the gas injected from the gas injection nozzles which does not contribute to the formation of the gas cluster. With this configuration, the pressure in the whole or a part of the processing chamber does not reach a high level at which the gas cluster is destroyed, and the processing using a gas cluster can be performed with high throughput without destroying the gas cluster.

### BRIEF DESCRIPTION OF THE DRAWINGS

FIG. 1 is a cross sectional view showing a substrate processing apparatus including a gas cluster irradiation mechanism in accordance with a first embodiment of the present invention.

FIG. 2 is a top view showing the gas cluster irradiation mechanism in accordance with the first embodiment of the present invention.

FIG. 3 schematically shows a state in which residual gases from neighboring gas injection nozzles which do not contribute to formation of a gas cluster are overlapped with each other.

FIG. 4 shows spread ranges of the residual gases which are obtained by simulation of gas flow injected from the gas injection nozzles.

FIG. 5 shows pressure distribution on a sample surface which is obtained based on the result shown in FIG. 4.

FIG. 6 is a top view showing a gas cluster irradiation mechanism in accordance with a second embodiment of the present invention.

### DETAILED DESCRIPTION OF THE EMBODIMENTS

Hereinafter, embodiments of the present invention will be described with reference to the accompanying drawings.

### First Embodiment

First, a first embodiment will be described.

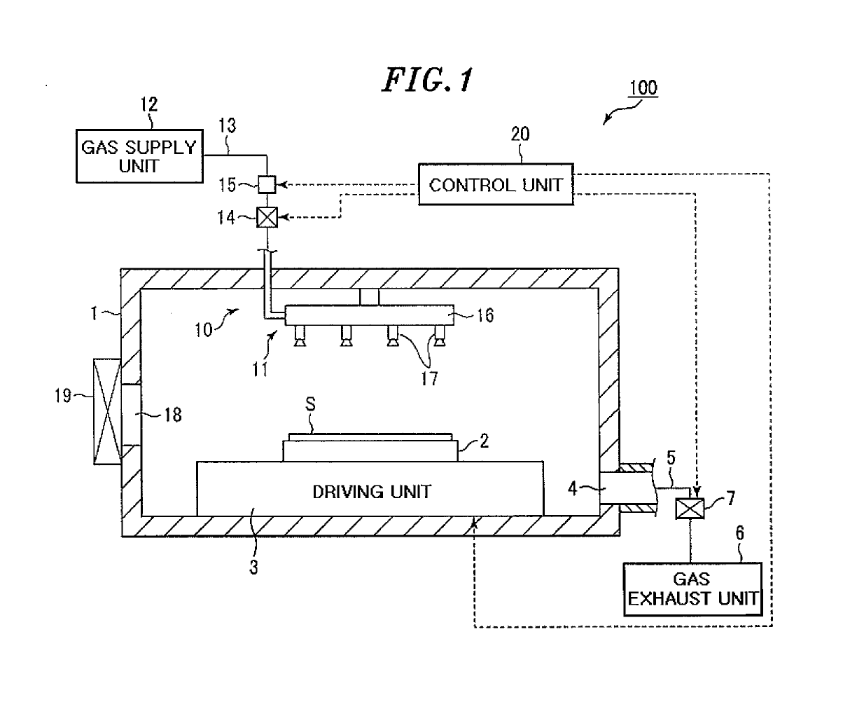

FIG. 1 is a cross sectional view showing a substrate processing apparatus including a gas cluster irradiation mechanism in accordance with a first embodiment of the present invention. FIG. 2 is a top view showing the gas cluster irradiation mechanism in accordance with the first embodiment of the present invention.

A substrate processing apparatus 100 processes a substrate by using a gas cluster. The processing of the substrate may be cleaning of the substrate, etching, removal of residue from the substrate after the etching, or the like.

The substrate processing apparatus 100 includes a processing chamber 1 for defining a processing space for processing the substrate. A substrate mounting table 2 is provided in the processing chamber 1 and a substrate to be processed S is mounted thereon. The substrate to be processed S is not particularly limited and may be various types of substrates such as a semiconductor wafer, a glass substrate for use in a flat panel display or the like. The substrate mounting table 2 can be moved in a plane by a driving unit 3, e.g., an XY table, so that the substrate to be processed S mounted thereon can also be moved in a plane.

A gas exhaust port 4 is provided at a lower portion of the sidewall of the processing chamber 1, and a gas exhaust line 5 is connected to the gas exhaust port 4. The gas exhaust line 5 is provided with a gas exhaust unit 6 having a vacuum pump or the like. The processing chamber 1 is exhausted to vacuum by the gas exhaust unit 6. The vacuum degree at this time can be controlled by the pressure control valve 7 provided on the gas exhaust line 5.

Provided above the substrate mounting table 2 is a gas cluster irradiation mechanism 10 for irradiating a gas cluster to the substrate to be processed S. The gas cluster irradiation mechanism 10 includes: a nozzle unit 11 disposed to face the substrate mounting table 2; a gas supply unit 12 for supplying a gas for generating a cluster to the nozzle unit 11; and a gas supply line 13 for guiding the gas from the gas supply unit 12 to the nozzle unit 11. The gas supply line 13 is provided with an opening/closing valve 14 and a flow rate controller 15. The nozzle unit 11 includes a header 16 and a plurality of (four in the drawing) gas injection nozzles 17 provided at the header 16. Further, the gas for generating a gas cluster which is supplied from the gas supply line 13 is injected from the gas injection nozzles 17 via the header 16. The gas injection nozzle 17 is configured as a conical nozzle having a leading end that becomes gradually wider. However, the shape of the gas injection nozzle 17 is not limited thereto, and the gas injection nozzle 17 may be configured as a small hole (orifice) formed in the header 16.

The gas injected from the gas injection nozzles 17 is adiabatically expanded in the processing chamber 1 that has been exhausted to vacuum by the gas exhaust unit 6, and several to tens of thousands of atoms or molecules of the gas are aggregated by van der Waals force. As a result, a gas cluster is generated. The gas cluster has a property of moving straight. The gas cluster that moves straight is irradiated onto the surface of the substrate to be processed S, so that a desired process, e.g., a cleaning process, is performed on the surface of the substrate to be processed S. When the cleaning process is carried out by the gas cluster, deposits that are not removed by a gas can be effectively removed. At this time, as a difference between the pressure in the processing chamber 1 and the gas pressure before the injection from the gas injection nozzles 17 is increased, the energy of collision between the gas cluster injected from the gas injection nozzles 17 and the substrate to be processed S is increased.

The gas for generating a gas cluster is not particularly limited and may be, e.g., Ar gas, N₂ gas, CO₂ gas, ClF₃ gas, HF gas or the like. Steam of liquid such as H₂O or the like may also be used. Such gases may be used separately or in combination with each other or with He gas.

A higher vacuum degree (i.e., a lower pressure) in the processing chamber 1 is preferred in order to inject the generated gas cluster to the substrate to be processed S without destroying the generated gas cluster. When the supply pressure of the gas to the nozzle unit 11 is 1 MPa or less, the vacuum degree in the processing chamber 1 is preferably 0.3 kPa or less. When the supply pressure is higher than 1 MPa and lower than or equal to 5 MPa, the vacuum degree in the processing chamber 1 is preferably 3 kPa or less.

In the present embodiment, a plurality of gas injection nozzles 17 is provided to increase a throughput. However, as the number of the gas injection nozzles 17 is increased, the gas flow rate is increased and the vacuum degree is decreased, which may lead to destruction of the gas cluster. Therefore, the number of the gas injection nozzles 17 is set such that when the gas is supplied from the gas injection nozzles 17 at a preset flow rate the pressure in the processing chamber 1 remains below a limit at which the gas cluster begins to be destroyed.

When the gas is injected from the gas injection nozzles 17, the residual gas that does not contribute to the formation of the gas cluster spreads. However, if the areas in which the residual gas from the gas injection nozzles 17 spreads are overlapped with each other, the vacuum degree is decreased (the pressure is increased) locally at that portion. Accordingly, the gas cluster is destroyed and the processing performance may deteriorate. To that end, in the present embodiment, neighboring gas injection nozzles 17 among the plurality of gas injection nozzle 17 are arranged so that the respective areas in which the residual gas therefrom spreads are not overlapped with each other, the residual gas being part of the gas injected from the gas injection nozzles 17 which does not contribute to the formation of the gas cluster.

Provided at a sidewall of the processing chamber 1 is a loading/unloading port 18 for loading and unloading the substrate to be processed S. The loading/unloading port 18 can be opened and closed by a gate valve 19. Further, the substrate processing apparatus 100 has a transfer unit for transferring the substrate and is connected to a load-lock chamber or a vacuum transfer chamber which is maintained in a vacuum state.

As described above, the driving unit 3 moves the substrate mounting table 2 in the plane, so that the nozzle unit 11 and the substrate to be processed S are relatively moved. The driving unit 3 moves the substrate mounting table 2 such that the gas cluster injected from the gas injection nozzles 17 is irradiated onto the entire surface of the substrate to be processed S on the substrate mounting table 2. Further, the driving unit may move the nozzle unit 11 instead of moving the substrate mounting table 2.

As shown in FIG. 1, the substrate processing apparatus 100 includes a control unit 20. The control unit 20 includes a controller having a microprocessor (computer) for controlling gas supply of the substrate processing apparatus 100 (the opening/closing valve 14 and the flow rate controller 15), gas exhaust (the pressure control valve 7), the driving of the substrate mounting table 2 by the driving unit 3 and the like. The controller is connected to a keyboard through which an operator inputs a command to manage the substrate processing apparatus 100, a display for visually displaying the operational states of the substrate processing apparatus 100, and the like. Further, the controller is connected to a storage unit that stores therein control programs to be used in realizing processes performed in the substrate processing apparatus 100 under the control of the controller, and control programs, i.e., processing recipes, to be used in controlling the respective components of the substrate processing apparatus 100 to carry out predetermined processes under processing conditions and various data. The recipes are stored in a suitable storage medium in the storage unit. If necessary, a predetermined recipe is read out from the storage unit and is executed by the controller. Accordingly, a desired process is performed in the substrate processing apparatus 100 under the control of the controller.

Hereinafter, a processing operation of the substrate processing apparatus 100 will be described.

First, the gate valve 19 is opened and the substrate to be processed S is loaded through the loading/unloading port 18 to be mounted on the substrate mounting table 2.

Next, the substrate mounting table 2 is set to an initial position by the driving unit 3. The processing chamber 1 is exhausted to vacuum by the gas exhaust unit 6, and a predetermined gas is injected from the gas injection nozzles 17 of the nozzle unit 11 at a predetermined flow rate. Hence, when the supply pressure of the gas to the nozzle unit 11 is 1 MPa or less, the processing chamber 1 is set to a vacuum state of 0.3 kPa or less, and when the supply pressure exceeds 1 MPa and is lower than or equal to 5 MPa, the processing chamber 1 is set to a vacuum state of 3 kPa or less. Further, the gas cluster is generated by adiabatic expansion of the gas injected from the gas injection nozzles 17. The gas cluster moves straight and collides with the substrate to be processed S on the substrate mounting table 2. Accordingly, a cleaning process or the like is performed. At this time, the substrate to be processed S is moved by the driving unit 3 so that the gas cluster can be irradiated onto the entirety of one side of the surface of the substrate to be processed S.

As described above, the gas cluster generated from a single gas injection nozzle is irradiated to an area of several mmφ. Therefore, in the case of processing a large substrate to be processed S by using a single gas injection nozzle, a throughput is low. To that end, in the present embodiment, a plurality of gas injection nozzles 17 is provided. However, if the number of gas injection nozzles is increased, the gas flow rate is increased and the vacuum degree is decreased. This may lead to destruction of the gas cluster. Accordingly, the plurality of the gas injection nozzles 17 is set such that when the gas is supplied from the gas injection nozzles at a preset flow rate a pressure in the processing chamber 1 remains below a limit at which the gas cluster begins to be destroyed.

For example, when a single gas injection nozzle for generating a gas cluster is provided, a gas flow rate is 700 sccm and a vacuum degree (pressure) in the processing chamber 1 is 1 Pa. Therefore, fifteen gas injection nozzles are provided in the case of processing the substrate while setting the vacuum degree in the processing chamber to 15 Pa at which the gas cluster is not destroyed.

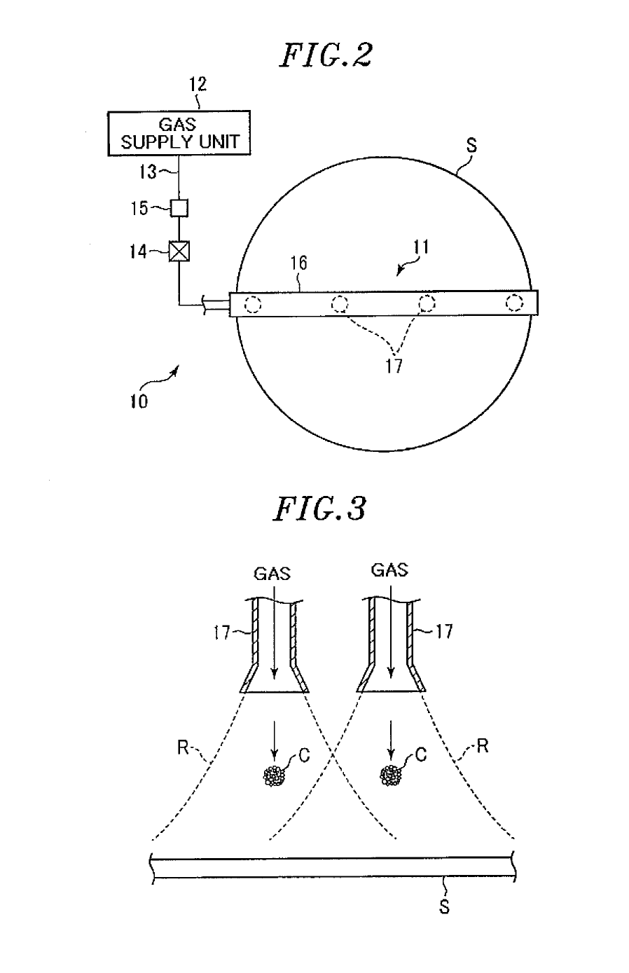

However, it was found that if the vacuum degree is locally low even when the average vacuum degree in the processing chamber 1 is proper, the cluster is destroyed at that portion and the processing performance deteriorates. It was also found that the reason that the vacuum degree is locally decreased is because neighboring gas injection nozzles 17 are disposed close to each other. In other words, as shown in FIG. 3, the gas cluster C is formed by injecting the gas from the gas injection nozzles 17, and the residual gas that does not contribute to the formation of the gas cluster spreads as indicated by dotted areas R. If the areas R where the residual gas spreads are overlapped with each other in the neighboring gas injection nozzles 17, the vacuum degree is decreased (the pressure is increased) locally at the portion. As a result, the gas cluster is destroyed and the processing performance may deteriorate.

Therefore, in the present embodiment, neighboring gas injection nozzles among a plurality of gas injection nozzles 17 are arranged so that the respective areas in which the residual gas therefrom spreads do not overlap with each other, the residual gas being part of the gas injected from the gas injection nozzles 17 that does not contribute to the formation of the gas cluster.

A result of simulation of gas flow injected from the gas injection nozzles which shows the actual spread range of the residual gas will be described. Here, CO₂ gas flow was simulated by using commercial fluid analysis software FLUENT Ver. 3. Conical nozzles were used as the gas injection nozzles, and a sample surface was made to face the gas injection nozzles. Calculation was carried out under three conditions A to C to be described in the following table 1.

TABLE 1

| | | Pressure in the |
|---|---|---|
| | CO₂ flow rate | processing chamber |
| Condition | Q CO₂ [sccm] | Pc [Pa] |
| A | 400 | 10 |
| B | 1200 | 22 |
| C | 2000 | 35 |

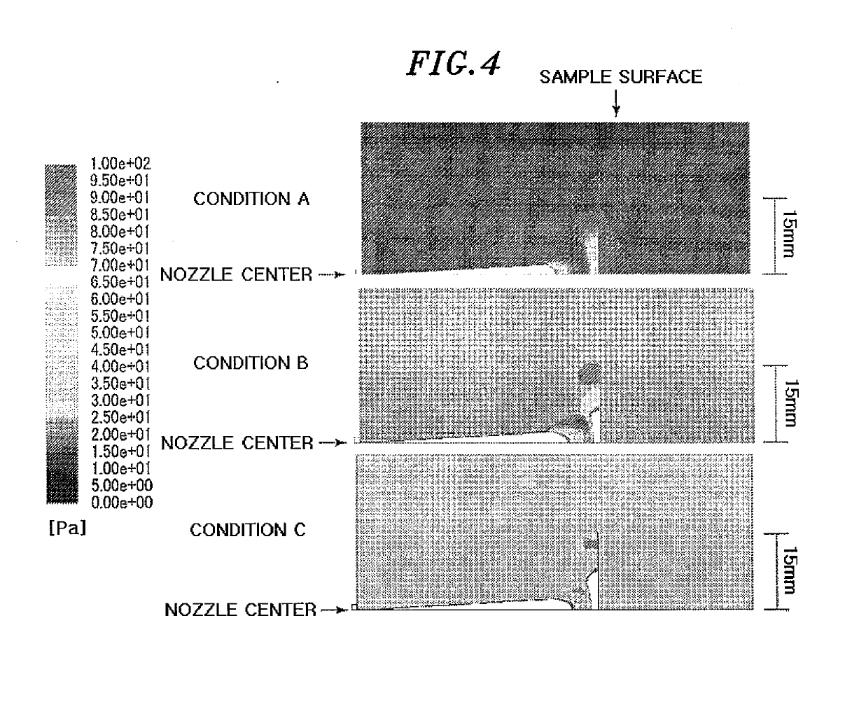

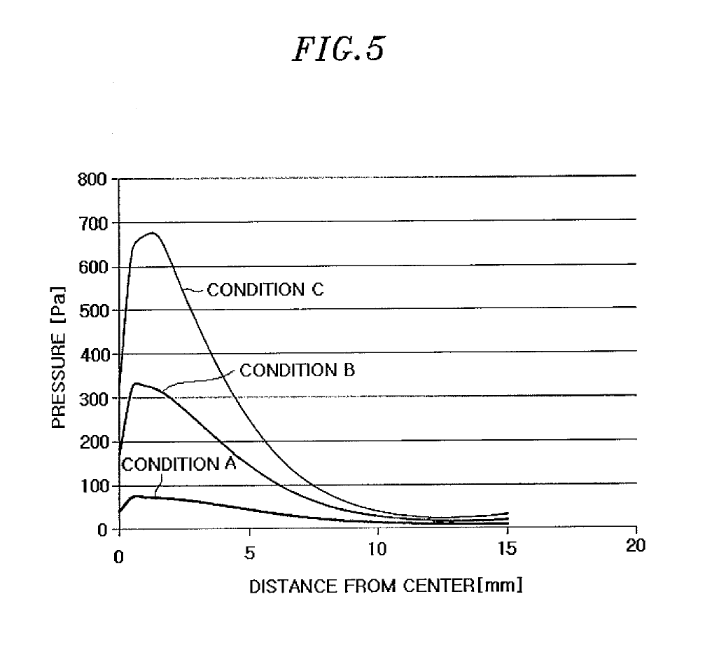

The simulation result is shown in FIG. 4. FIG. 4 shows pressure distribution of the gas in the case of injecting CO₂ gas from the nozzles under the respective conditions. FIG. 5 shows pressure distribution on the sample surface which is obtained based on the result shown in FIG. 4. A horizontal axis in FIG. 5 indicates a distance from the nozzle center.

As shown in the drawing, in any of the conditions A to C, the pressure is highest near the nozzle on the sample surface and a bulk pressure is obtained at around 10 mm from the nozzle center. This result shows that the CO₂ gas injected from the nozzle spreads within a range of a radius of 10 mm regardless of the pressure. From the above simulation result, it is preferable to separate the neighboring gas injection nozzles 17 from each other by a distance of 20 mm or greater.

For example, in the above case of providing fifteen gas injection nozzles each capable of setting the vacuum degree (pressure) in the processing chamber 1 to 1 Pa and processing a wafer having a diameter of 300 mm as the substrate while setting the pressure in the processing chamber to 15 Pa, the fifteen gas injection nozzles are separated from each other at an interval of 20 mm as described above so that they can be arranged in one row along the diameter of the 300 mm wafer.

### Second Embodiment

Hereinafter, a second embodiment will be described.

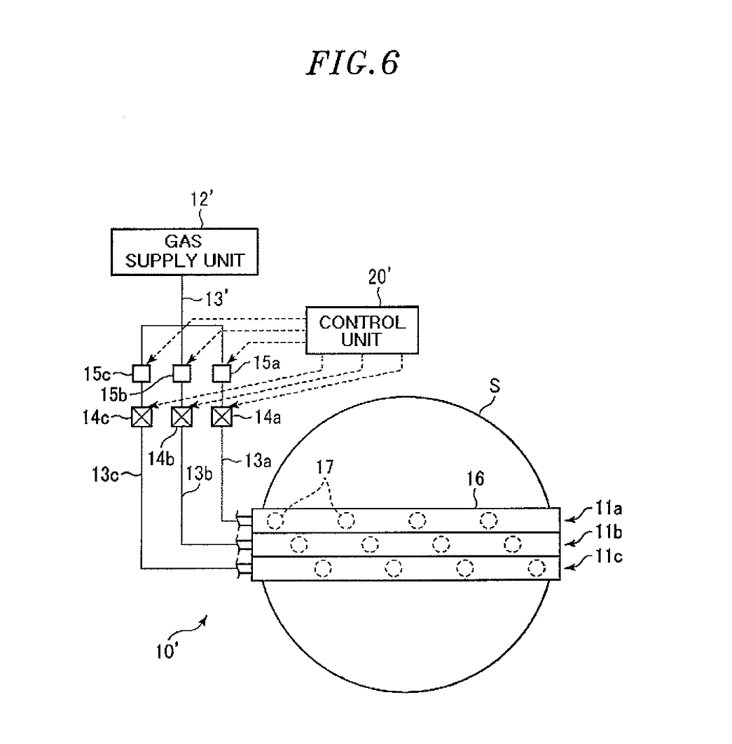

FIG. 6 is a top view showing a gas cluster irradiation mechanism in accordance with a second embodiment of the present invention.

As shown in FIG. 6, a gas cluster irradiation mechanism 10′ of the present embodiment includes: three nozzle units 11a, 11b and 11c disposed to face a substrate mounting table 2 (not shown in FIG. 6); a gas supply unit 12′ for supplying a gas for generating a cluster to the nozzle units 11a to 11c; and a gas supply line for guiding the gas from the gas supply unit 12′ to the nozzle units 11a to 11c. The gas supply line includes a common pipeline 13′ extending from the gas supply unit 12′, and branch lines 13a to 13c branched from the common pipeline 13′ and connected to the nozzle units 11a to 11c, respectively. The branch lines 13a to 13c are provided with opening/closing valves 14a to 14c and flow rate controllers 15a to 15c, respectively. As in the case of the nozzle unit 11, each of the nozzle units 11a to 11c has a header 16 and a plurality of (four in the drawing) gas injection nozzles 17 formed at the header 16. Further, the gas for generating the gas cluster is injected from the gas injection nozzles 17 through the headers 16 of the nozzle units 11a to 11c. The nozzle units 11a to 11c are formed as one unit.

As in the case of the nozzle unit 11 of the first embodiment, each of the nozzle units 11a to 11c has gas injection nozzles 17. The plurality of the gas injection nozzles 17 is set such that when the gas is supplied from the gas injection nozzles at a preset flow rate a pressure in the processing chamber 1 remains below a limit at which the gas cluster begins to be destroyed. Further, as in the case of the nozzle unit 11, the gas injection nozzles 17 of the nozzle units 11a to 11c are arranged with a preset interval between neighboring gas injection nozzles such that the respective areas in which residual gas from the neighboring gas injection nozzles spreads do not overlap with each other, the residual gas being part of the gas injected from the gas injection nozzles 17 and not contributing to generation of the gas cluster.

Moreover, the opening/closing valves 14a to 14c of the nozzle units 11a to 11c are controlled to be sequentially opened by a control unit 20′, so that the gas cluster can be irradiated at different timings from the nozzle units 11a to 11c. Hence, a higher throughput can be obtained while suppressing the deterioration of the processing performance which is caused by the decrease in the vacuum degree in the whole or a part of the processing chamber 1.

At this time, by misaligning the positions of the gas injection nozzles 17 of the adjacent nozzle units as shown in FIG. 6, the horizontal movement of the nozzles units 11a to 11c by the driving unit 3 (not shown in FIG. 6) can be reduced and, thus, the throughput can be further increased. Especially, it is preferable to set a misalignment distance between the gas injection nozzles 17 of the adjacent nozzle units to be smaller than or equal to the irradiation area of the cluster injected from a single gas injection nozzle and also preferable to set the number of nozzle units so that the gas cluster can be irradiated from the gas injection nozzles to the entire surface of the substrate to be processed S in the diametrical direction of the substrate to be processed S. In the example of FIG. 6, the gas injection nozzles 17 of the nozzle units 11a to 11c are misaligned slightly so that the gas cluster can be irradiated to the entire surface of the substrate to be processed S in the diametrical direction of the substrate to be processed S. As a consequence, the substrate to be processed S can be moved in one direction by the driving unit 3, which makes it possible to obtain an extremely high throughput.

For example, in the above-described case of providing fifteen gas injection nozzles each capable of setting a vacuum degree (pressure) in the processing chamber 1 to 1 Pa and processing a wafer having a diameter of 300 mm while setting the pressure in the processing chamber to 15 Pa, the fifteen gas injection nozzles are provided at a single nozzle while being spaced from each other at an interval of 20 mm. If the gas cluster is irradiated to an area of 4 mm, the gas cluster can be irradiated to the entire surface of the 300 mm wafer by providing five nozzle units in which the gas injection nozzles are spaced from each other by a distance of 4 mm. Since the gas is injected from each of the nozzle units sequentially, the processing can be performed with extremely high throughput while moving the wafer in one direction.

### OTHER APPLICATIONS

The present invention may be variously modified without being limited to the above embodiment. For example, in the above embodiment, the gas injection nozzles of the nozzle unit are arranged in one row. However, the present invention is not limited thereto.

Further, the above embodiment has described an example in which the gas cluster irradiation mechanism of the present invention is used for a single-purpose apparatus for performing a cleaning process or the like of the substrate. However, the present invention is not limited thereto. For example, in the case of performing a process of removing residue from the substrate after etching or ashing, the gas cluster irradiation mechanism of the present invention is provided in the load-lock chamber for transferring the substrate in the atmospheric atmosphere to an etching chamber or an ashing chamber in a vacuum state or to a vacuum transfer chamber connected to the processing chamber, e.g., the etching chamber, the ashing chamber or the like. After the etching or the ashing is completed, the process of removing residue from the substrate can be performed in such a chamber by using the gas cluster during the transfer of the substrate. In that case, the gas cluster can be irradiated while moving the substrate to be processed mounted on the transfer arm installed in the system without providing the substrate mounting table and the driving unit.

While the invention has been shown and described with respect to the embodiments, it will be understood by those skilled in the art that various changes and modifications may be made without departing from the scope of the invention as defined in the following claims.

What is claimed is:

1. A gas cluster irradiation mechanism for generating a gas cluster by adiabatic expansion of a gas and irradiating the gas cluster onto a substrate to be processed in the processing chamber, the gas cluster irradiation mechanism comprising:
at least one nozzle unit including a plurality of gas injection nozzles configured to inject the gas into the processing chamber which is maintained in a vacuum state; and
a gas supply unit configured to supply the gas to the nozzle unit,
wherein the number of gas injection nozzles is set such that when the gas is supplied from the gas injection nozzles at a preset flow rate a pressure in the processing chamber remains below a limit at which the gas cluster begins to be destroyed, and
wherein the gas injection nozzles are arranged with a preset interval between neighboring gas injection nozzle such that respective areas in which residual gas from the neighboring gas injection nozzles spreads do not overlap with each other, the residual gas being part of the gas injected from the gas injection nozzles and not contributing to generation of the gas cluster.

2. The gas cluster irradiation mechanism of claim 1, wherein the pressure in the processing chamber is 0.3 kPa or less when a supply pressure of the gas to said at least one nozzle unit is 1 MPa or less and the pressure in the processing chamber is 3 kPa or less when the supply pressure is greater than 1 MPa and smaller than or equal to 5 MPa.

3. The gas cluster irradiation mechanism of claim 1, wherein a distance between the neighboring gas injection nozzles among the number of the gas injection nozzles is 20 mm or greater.

4. The gas cluster irradiation mechanism of claim 1, wherein said at least one nozzle unit and the substrate to be processed are relatively movable with respect to each other, and the gas cluster is irradiated onto the entirety of one side of the substrate to be processed while relatively moving said at least one nozzle unit and the substrate to be processed.

5. The gas cluster irradiation mechanism of claim 1, wherein said at least one nozzle unit comprises a plurality of nozzle units which are configured such that the gas is injected from each of the plurality of nozzle units sequentially.

6. The gas cluster irradiation mechanism of claim 5, wherein positions of corresponding gas injection nozzles of adjacent nozzle units among the plurality of nozzle units are misaligned.

7. The gas cluster irradiation mechanism of claim 6, wherein a misalignment distance of the corresponding gas injection nozzles of the adjacent nozzle units is smaller than or equal to an irradiation range of the gas cluster from a single gas injection nozzle, and
wherein the number is set such that an irradiation range of the gas cluster from the entirety of the gas injection nozzles cover the entirety of the substrate to be processed in a diametrical direction of the substrate to be processed.

8. The gas cluster irradiation mechanism of claim 1, wherein the gas cluster irradiation mechanism is configured to be provided in a vacuum transfer chamber or a load-lock chamber for transferring the substrate to be processed to the processing chamber, and the gas cluster irradiation mechanism is configured such that the gas cluster is irradiated in a state where the substrate to be processed is mounted on a transfer arm which transfers the substrate to be processed.

9. A substrate processing apparatus for performing predetermined processing on a substrate to be processed by using a gas cluster, comprising:
a processing chamber maintained in a vacuum state;
a substrate supporting unit configured to support the substrate to be processed in the processing chamber; and
a gas cluster irradiation mechanism for generating the gas cluster by adiabatic expansion a gas into the processing chamber and irradiating the gas cluster onto the substrate to be processed,
wherein the gas cluster irradiation mechanism includes:
at least one nozzle unit having a plurality of gas injection nozzles configured to inject the gas into the processing chamber which is maintained in a vacuum state; and
a gas supply unit configured to supply the gas to the nozzle unit,
wherein the number of the nozzle unit is set such that when the gas is supplied from the gas injection nozzles at a preset flow rate a pressure in the processing chamber remains below a limit at which the gas cluster begins to be destroyed, and
wherein the gas injection nozzles are arranged with a preset interval between neighboring gas injection nozzles such that respective areas in which residual gas from the neighboring gas injection nozzles spreads do not overlap with each other, the residual gas being part of the gas injected from the gas injection nozzles and not contributing to generation of the gas cluster.

10. The substrate processing apparatus of claim 9, wherein the pressure in the processing chamber is 0.3 kPa or less when the supply pressure of the gas to said at least one nozzle unit is 1 MPa or less and the pressure in the processing chamber is 3 kPa or less when the supply pressure is 5 MPa or less.

11. The substrate processing apparatus of claim 9, wherein a distance between the neighboring gas injection nozzles among the plurality of the gas injection nozzles is greater than or equal to 20 mm.

12. The substrate processing apparatus of claim 9, further comprising a driving unit for relatively moving the nozzle unit and the substrate to be processed with respect to each other,
wherein the gas cluster irradiation mechanism irradiates the gas cluster onto the entirety of one side of the substrate to be processed while relatively moving the nozzle unit and the substrate to be processed.

13. The substrate processing apparatus of claim 9, wherein said at least one nozzle unit includes a plurality of nozzle units which are configured such that the gas is injected from each of the plurality of nozzle units sequentially.

14. The substrate processing apparatus of claim 13, wherein positions of corresponding gas injection nozzle of adjacent nozzles units among the plurality of nozzle units are misaligned.

15. The substrate processing apparatus of claim 14, wherein a misalignment distance of the corresponding gas injection nozzles of the adjacent nozzle units is smaller than or equal to an irradiation range of the gas cluster from a single gas injection nozzle, and
wherein the number of the nozzle units is set such that an irradiation rage of the gas cluster from the entirety of the gas injection nozzles covers the entirety of the substrate to be processed in a diametrical direction of the substrate to be processed.

16. The substrate processing apparatus of claim 9, wherein the processing chamber is a vacuum transfer chamber or a load-lock chamber for transferring the substrate to be processed to the processing chamber, and the gas cluster is irradiated from the gas cluster irradiation mechanism in a state where the substrate to be processed is mounted on a transfer arm which transfers the substrate to be processed.

17. A gas cluster processing method, comprising:
generating a gas cluster by adiabatic expansion by injecting a gas into a processing chamber maintained in a vacuum state and irradiating the gas cluster onto a substrate to be processed in the processing chamber,
wherein the number of the gas injection nozzles is set such that when the gas is supplied from the gas injection nozzles at a preset flow rate a pressure in the processing chamber remains below a limit at which the gas cluster begins to be destroyed, and
wherein the gas injection nozzles are arranged with a preset interval between neighboring gas injection nozzles such that respective areas in which residual gas from the neighboring gas injection nozzles spreads do not overlap with each other, the residual gas being part of the gas injected from the gas injection nozzles and not contributing to generation of the gas cluster.
